(19) United States
(12) Patent Application Publication
(10) Pub. No.: US 2009/0213557 A1
(43) Pub. Date: Aug. 27, 2009

(54) ELECTRONIC DEVICE WITH INTERNAL MICROPHONES DISPOSED IN FLEXIBLE HOLDERS

(75) Inventor: Ming-Hsun Wen, Cupertino, CA (US)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: FORTEMEDIA, INC., Cupertino, CA (US)

(21) Appl. No.: 12/140,340

(22) Filed: Jun. 17, 2008

Related U.S. Application Data
(60) Provisional application No. 61/030,247, filed on Feb. 21, 2008.

(51) Int. Cl. H05K 7/00

(52) U.S. Cl. 361/748; 381/365

(57) ABSTRACT

An electronic device includes a housing, a circuit board, a plurality of flexible holders, and a plurality of microphones. The housing includes a plurality of wall portions, a plurality of storage spaces encircled by the wall portions, and a plurality of acoustic openings connected to the storage spaces. The flexible holders are disposed in the storage spaces. Each of the flexible holders comprises a plurality of surfaces and at least one rib provided on the surfaces. The microphones are mounted on the circuit board and disposed in the flexible holders.

### CROSS REFERENCE TO RELATED APPLICATIONS

This application claims the benefit of U.S. Provisional Application No. 61/030,247, filed Feb. 21, 2008.

### BACKGROUND OF THE INVENTION

1. Field of the Invention

The invention relates to an electronic device, and more particularly to an electronic device with internal microphones disposed in flexible holders, capable of adequate performance.

2. Description of the Related Art

A microphone array is capable of clearly receiving sound from a particular direction while excluding surrounding noise, and is often applied in high-quality audio recorders or communications devices.

A typical microphone array includes a number of microphones disposed in tandem. Referring to FIG. 1, a simple example is shown wherein the microphone array 1 includes two microphones 11 and 12 placed side by side. Directivities of the microphone array 1 can be achieved by manipulating the signal received by the two microphones 11 and 12. Assuming the two microphones 11 and 12 are omni-directional and have the same characteristics, the directivity of the microphone array 10 depends on the distance d between the two microphones 11 and 12.

The disclosed microphones 11 and 12 are placed in an open space for achieving directivity. Most electronic devices (cellular phones, personal digital assistants, notebook computers, etc.), however, have plastic or metal housings, which are acoustic isolators. Acoustic isolators block audio signals, increasing difficulty for microphone placement. Specifically, microphone array performance, acceptable in an open space, deteriorates when disposed in a housing of an electronic device, because reception of external sound is hindered by the housing. Also, sound leakage and cross talk problems between the microphones must be prevented when the microphone array is disposed in the housing of an electronic device.

### BRIEF SUMMARY OF THE INVENTION

The invention provides an electronic device comprising internal microphones disposed in flexible holders, capable of adequate performance.

The electronic device in accordance with an exemplary embodiment of the invention includes a housing, a circuit board, a plurality of flexible holders, and a plurality of microphones. The housing includes a plurality of wall portions, a plurality of storage spaces encircled by the wall portions, and a plurality of acoustic openings connected to the storage spaces. The flexible holders are disposed in the storage spaces. Each of the flexible holders comprises a plurality of surfaces and at least one rib provided on the surfaces. The microphones are mounted on the circuit board and disposed in the flexible holders.

In another exemplary embodiment, the surfaces of each of the flexible holders include a front surface, a rear surface, and a plurality of side surfaces connected between the front surface and the rear surface, wherein the rib is provided on the front surface.

In yet another exemplary embodiment, the front surface of each of the flexible holders has a first hole, and the first hole is encircled by the rib and connected to one of the acoustic openings.

In another exemplary embodiment, the rear surface of each of the flexible holders has a second hole, wherein the diameter of the second hole exceeds that of the first hole.

In yet another exemplary embodiment, the surfaces of each of the flexible holders include a front surface, a rear surface, and a plurality of side surfaces connected between the front surface and the rear surface, wherein the rib is provided on the side surfaces.

In another exemplary embodiment, the front surface of each of the flexible holders has a first hole, and the first hole is connected to one of the acoustic openings.

In yet another exemplary embodiment, the rear surface of each of the flexible holders has a second hole, and the diameter of the second hole exceeds that of the first hole.

In another exemplary embodiment, the flexible holders are substantially cylindrical.

In yet another exemplary embodiment, the flexible holders are made of rubber.

In another exemplary embodiment, the microphones constitute a microphone array.

The invention also provides a flexible holder. The flexible holder in accordance with an exemplary embodiment of the invention includes a front surface, a rear surface, a plurality of side surfaces, a first hole, a second hole, and a rib. The side surfaces are connected between the front surface and the rear surface. The first hole is provided on the front surface. The second hole is provided on the rear surface, wherein the diameter of the second hole exceeds that of the first hole. The rib is provided on the front surface or the side surfaces.

In another exemplary embodiment, the first hole is encircled by the rib when the rib is provided on the front surface.

In yet another exemplary embodiment, the flexible holder is substantially cylindrical.

In another exemplary embodiment, the flexible holder is made of rubber.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 depicts a microphone array including two microphones placed side by side;

FIG. 2A is a schematic view showing an electronic device with an internal microphone array in accordance with an embodiment of the invention;

FIG. 2B is a sectional view of FIG. 2A along line IIB-IIB;

FIG. 3A is a sectional view of a flexible holder of a first example in accordance with the invention;

FIG. 3B is a perspective diagram of the flexible holder of FIG. 3A, with the rear surface upward;

FIG. 3C is a perspective diagram of the flexible holder of FIG. 3A, with the front surface upward;

FIG. 4A is a sectional view of a flexible holder of a second example in accordance with the invention;

FIG. 4B is a perspective diagram of the flexible holder of FIG. 4A, with the rear surface upward;

FIG. 4C is a perspective diagram of the flexible holder of FIG. 4A, with the front surface upward;

FIG. 5A depicts a tested flexible holder of the first example;

FIG. 5B depicts a tested flexible holder of the second example;

FIG. 6A is a sectional view of a test jig for holding the tested flexible holders of FIGS. 5A and 5B;

FIG. 6B is a perspective diagram of the test jig of FIG. 6A;

FIG. 7 depicts a polar pattern for two omni-directional microphones disposed in the tested flexible holders of FIGS. 5A and 5B and a first jig;

FIG. 8 depicts a polar pattern for two omni-directional microphones disposed in the tested flexible holders of FIGS. 5A and 5B and a second jig;

FIG. 9 depicts a polar pattern for two omni-directional microphones disposed in the tested flexible holders of FIGS. 5A and 5B and a third jig;

FIG. 10 depicts a polar pattern for two omni-directional microphones disposed in the tested flexible holders of FIGS. 5A and 5B and a fourth jig; and

FIG. 11 depicts a polar pattern for two omni-directional microphones disposed in the tested flexible holders of FIGS. 5A and 5B and a fifth jig.

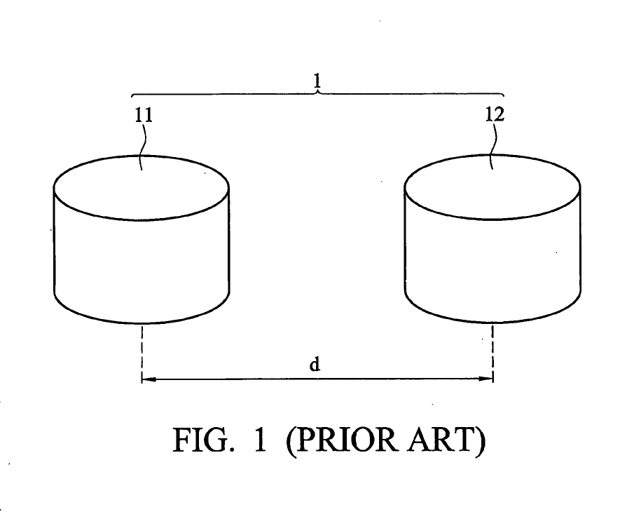

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

While a notebook computer is utilized for purposes of illustration, it is understood that the invention is equally applicable to a variety of electronic devices including cellular phones, personal digital assistants (PDAs), global positioning system (GPS) receivers, liquid crystal displays (LCDs), speakerphones, and others.

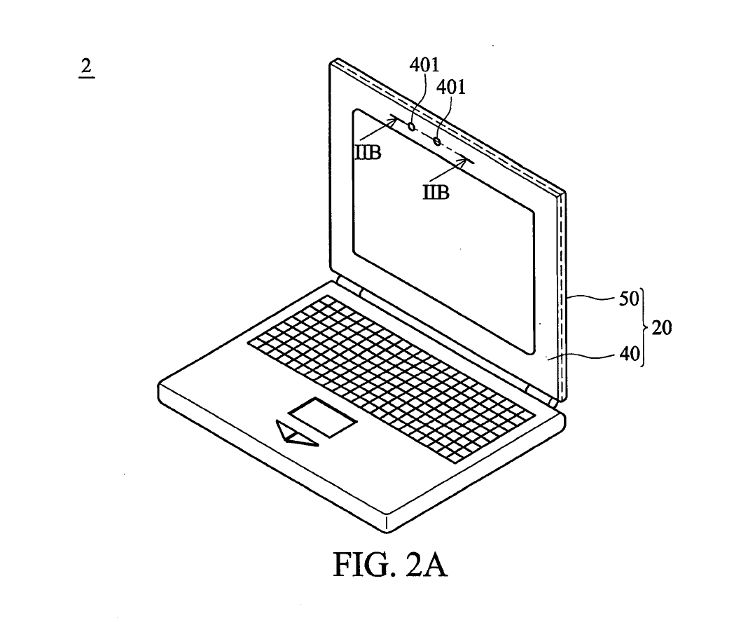

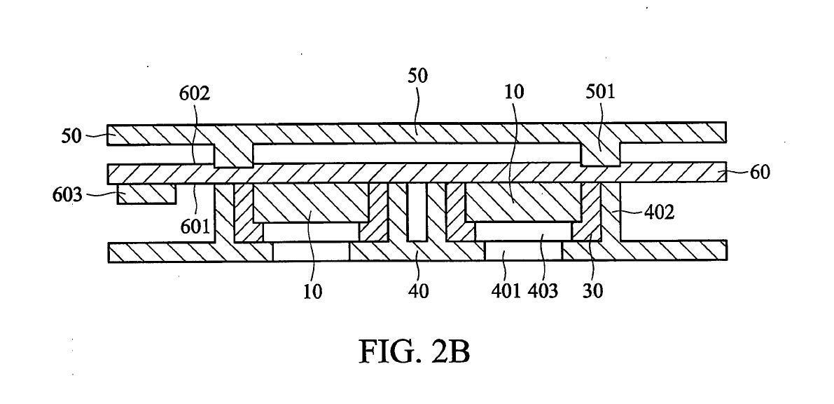

Referring to FIG. 2A, an electronic device 2 of an embodiment of the invention includes a housing 20. The housing 20 includes a front cover 40 and a rear cover 50. A plurality of acoustic openings 401 is provided in the front cover 40 allowing external sound to enter.

Referring to FIG. 2B, the front cover 40 has a plurality of wall portions 402 protruding inward to form a plurality of storage spaces 403. That is, the storage spaces 403 are encircled by the wall portions 402. Also, the acoustic openings 401 of the front cover 40 are connected to the storage spaces 403.

A circuit board 60 has a first surface 601, a second surface 602 opposing the first surface 601, and an integrated circuit chip 603 mounted on the first surface 601. Two omni-directional microphones 10, mounted on the first surface 601 of the circuit board 60, constitute a microphone array. The two omni-directional microphones 10 are fitted into two flexible holders 30 and then disposed in the storage spaces 403. Thus, the omni-directional microphones 10 are capable of receiving external sound via the acoustic opening 401 of the front cover 40.

In FIG. 2B, the integrated circuit chip 603 is mounted on the first surface 601 of the circuit board 60. However, it is understood that the integrated circuit chip 603 may be mounted on the second surface 602 or even disposed in at least one of the omni-directional microphones 10.

A plurality of protrusions 501 protrudes from the rear cover 50 and pushes the circuit board 60 toward the front cover 40.

The flexible holders 30 may be made of rubber or other flexible materials, to not only protect the internal omni-directional microphones 10 from vibrations, but also prevent sound leakage and cross talk between the internal omni-directional microphones 10. To begin, the flexible holders 30 are slightly larger than the storage spaces 403. However, the protrusions 501 of the rear cover 50 push the circuit board 60 toward the front cover 40. Thus, the flexible holders 30 are squeezed and contracted until the circuit board 60 contacts the wall portions 402 of the front cover 40. As a result, the flexible holders 30 are tightly held between the omni-directional microphones 10 and the front cover 40 to avoid any sound leakage. Also, the omni-directional microphones 10 in the storage spaces 403 can only receive external sound via the acoustic openings 401. Thus, the omni-directional microphones 10 are capable of adequate performance.

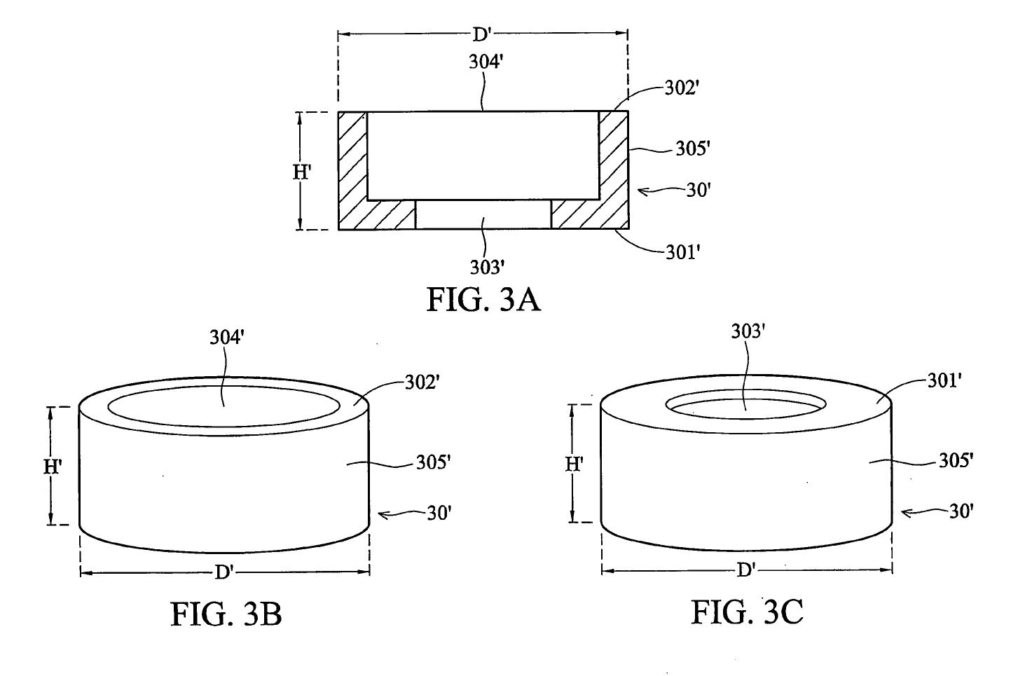

Referring to FIGS. 3A, 3B, and 3C, a flexible holder 30′ of a first example is substantially cylindrical, having a front surface 301′, a rear surface 302′, and a plurality of side surfaces 305′ connected between the front surface 301′ and the rear surface 302′. A first hole 303′ is provided on the front surface 301′ for the microphone 10 to receive sound. A second hole 304′ is provided on the rear surface 302′ for insertion of the microphone 10 into the flexible holder 30′. The diameter of the second hole 304′ exceeds that of the first hole 303′.

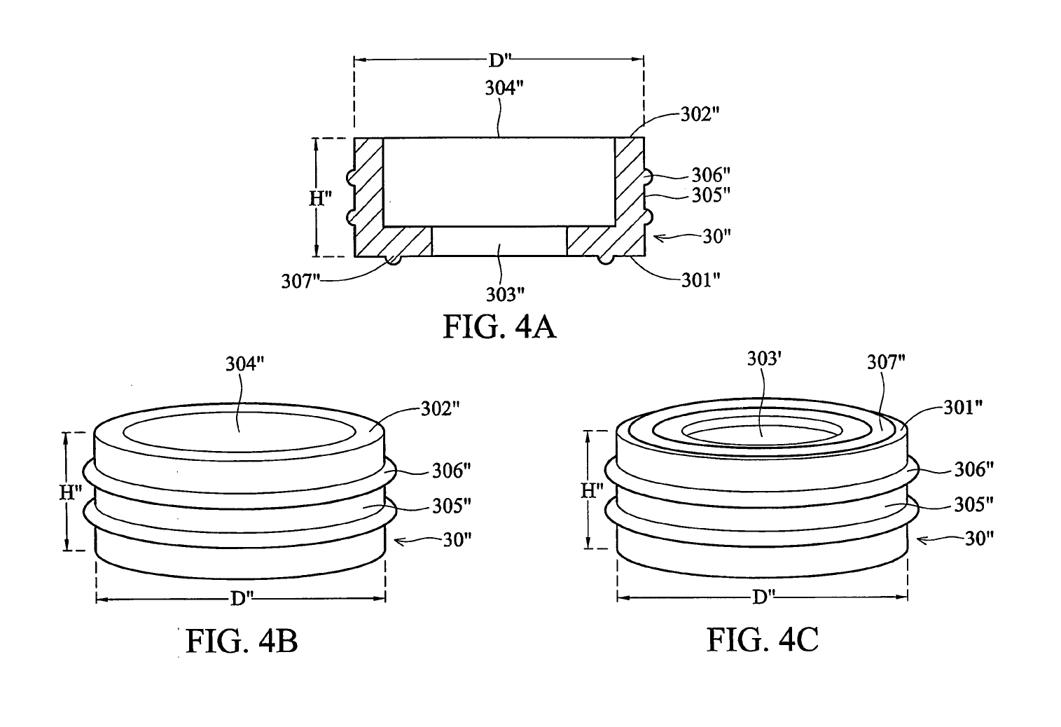

Referring to FIGS. 4A, 4B, and 4C, a flexible holder 30″ of a second example is substantially cylindrical, having a front surface 301″, a rear surface 302″, and a plurality of side surfaces 305″ connected between the front surface 301″ and the rear surface 302″. A first hole 303″ is provided on the front surface 301″ for the microphone 10 to receive sound. A second hole 304″ is provided on the rear surface 302″ for insertion of the microphone 10 into the flexible holder 30″. The diameter of the second hole 304″ exceeds that of the first hole 303″. At least one round rib 307″ is provided on the front surface 301″ and encircles the first hole 303″. One or more round ribs 306″ are circumferentially provided on the side surfaces 305″.

As described, it is required that the flexible holders 30 are tightly held between the omni-directional microphones 10 and the front cover 40 to avoid any sound leakage. To achieve this, the dimensional tolerance of the storage space 403 which accommodates the flexible holder 30 is necessarily controlled (“dimensional tolerance” is defined as the permissible or acceptable variation in the dimensions of a part). However, a narrow tolerance range is economically undesirable.

As compared to the flexible holder 30′ of the first example, the flexible holder 30″ of the second example allowed a wider tolerance range of the storage space 403 without sound leakage due to the round ribs 306″ and 307″, which was verified in tests, of which will be described as follows.

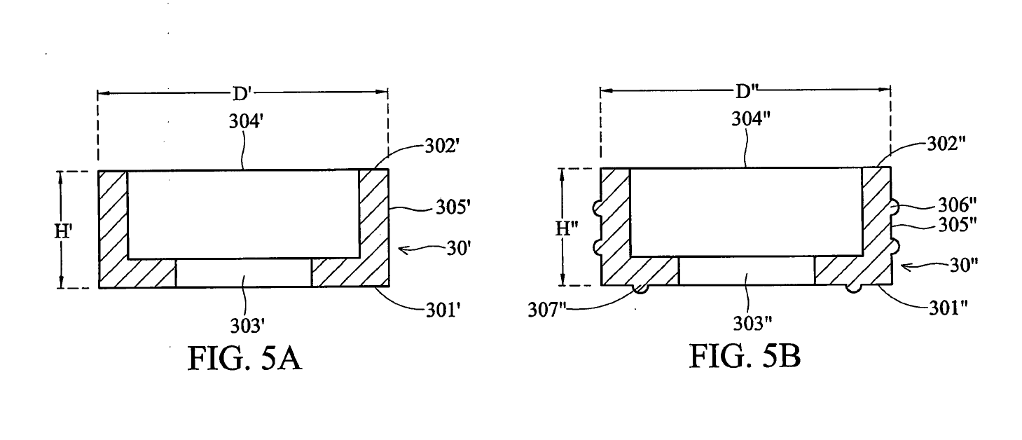

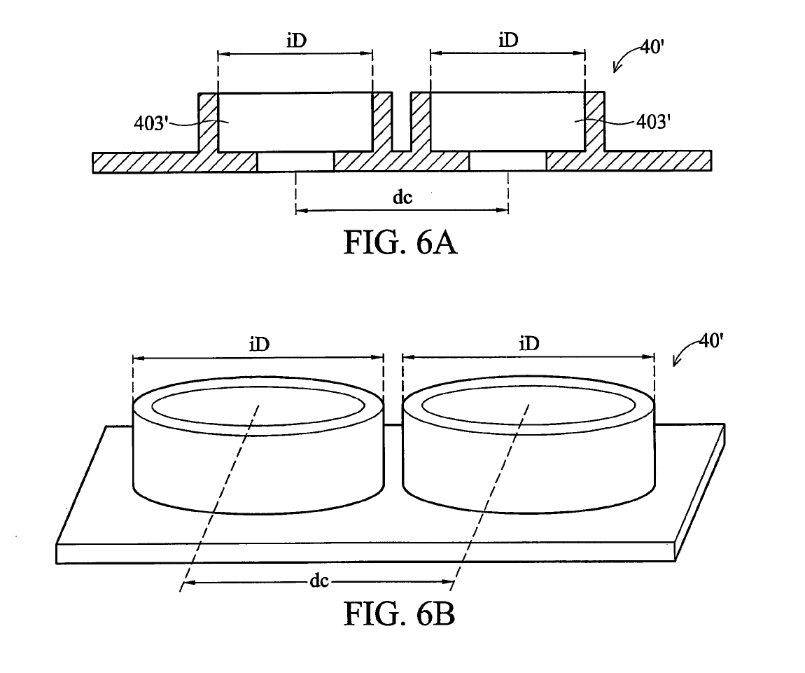

FIG. 5A depicts the tested flexible holder of the first example (hereinafter Holder I), wherein the height and the outer diameter of the holder I are indicated by H′ and D′, respectively. FIG. 5B depicts the tested flexible holder of the second example (hereinafter Holder II), wherein the height and the outer diameter of the holder II are indicated by H″ and D″, respectively. FIGS. 6A and 6B depict the test jig 40′ for holding the tested flexible holders (Holders I and II). The test jig 40′ had two storage spaces 403′. Each storage space 403′ had an inner diameter iD. The distance between the centers of the storage space 403′ was dc.

A sound level meter was placed 25 cm from a loudspeaker. The volume of the loudspeaker was turned up until the sound level meter read 94 dB. Then, the sound level meter was replaced with the test jig in which two tested flexible holders (Holders I or II) and two omni-directional microphones (a main microphone and a reference microphone) were disposed.

Five test jigs of different dimensions were used. In the first test jig, the inner diameter iD=7.85 mm, and the distance of centers dc=10.35 mm. In the second test jig, the inner diameter iD=8.15 mm, and the distance of centers dc=10.35 mm. In the third test jig (standard jig), the inner diameter iD=8.0 mm, and the distance of centers dc=10.5 mm. In the fourth test jig, the inner diameter iD=8.15 mm, and the distance of centers dc=10.65 mm. In the fifth test jig, the inner diameter iD=7.85 mm, and the distance of centers dc=10.65. Table I shows the test result, made on Dec. 12, 2007.

TABLE I

| | Main- | | Main- | |
|---|---|---|---|---|
| | MicSens | RefMicSens | Leakage | RefLeakage |
| Jig 1 + Holder I | −18.9 dB | −19.9 dB | 30.8 dB | 28.7 dB |
| Jig 1 + Holder I | −18.8 dB | −19.7 dB | 31.7 dB | 28.7 dB |
| Jig 1 + Holder II | −18.1 dB | −19.4 dB | 30.1 dB | 26.2 dB |
| Jig 1 + Holder II | −17.9 dB | −19 dB | 29 dB | 26.7 dB |
| Jig 2 + Holder I | −20.4 dB | −21.1 dB | 7.9 dB | 23.3 dB |
| Jig 2 + Holder I | −21 dB | −22 dB | 9.4 dB | 8.7 dB |
| Jig 2 + Holder I | −20.5 dB | −21.8 dB | 10 dB | 9 dB |
| Jig 2 + Holder II | −19 dB | −20 dB | 24.6 dB | 22.6 dB |
| Jig 2 + Holder II | −18.6 dB | −20 dB | 52.7 dB | 22.4 dB |
| Jig 3 + Holder I | −25.3 dB | −26.1 dB | 26.5 dB | 21.1 dB |
| Jig 3 + Holder I | −19.4 dB | −20.8 dB | 53.2 dB | 24.6 dB |
| Jig 3 + Holder I | −19.6 dB | −20.5 dB | 52.8 dB | 25.5 dB |
| Jig 3 + Holder II | −18.1 dB | −19.4 dB | 27.1 dB | 25.1 dB |
| Jig 3 + Holder II | −17.8 dB | −19.2 dB | 27.7 dB | 25.5 dB |
| Jig 4 + Holder I | −20.4 dB | −20.8 dB | 6.5 dB | 26 dB |
| Jig 4 + Holder I | −20.7 dB | −21 dB | 6.2 dB | 25.2 dB |
| Jig 4 + Holder II | −18.1 dB | −19.4 dB | 27.1 dB | 24.2 dB |
| Jig 4 + Holder II | −18 dB | −19.2 dB | 26.6 dB | 24.2 dB |
| Jig 5 + Holder I | −19 dB | −20.1 dB | 31.3 dB | 29.5 dB |
| Jig 5 + Holder I | −19.1 dB | −19.9 dB | 30.8 dB | 29.5 dB |
| Jig 5 + Holder I | −19.7 dB | −20.6 dB | 30.2 dB | 29.5 dB |
| Jig 5 + Holder II | −16.9 dB | −19.3 dB | 30.8 dB | 25 dB |
| Jig 5 + Holder II | −17 dB | −19.2 dB | 53.2 dB | 24.2 dB |
| Jig 5 + Holder II | −17.2 dB | −19.1 dB | 29.8 dB | 25.3 dB |
| Jig 5 + Holder II | −16.2 dB | −18.4 dB | 31.3 dB | 25.4 dB |
| Jig 5 + Holder II | −16.2 dB | −18.4 dB | 53.2 dB | 25.7 dB |

As shown, when jig 1 and Holder I were used for the test, the sound pressures received by the main microphone and the reference microphone were −18.9 dB and −19.9 dB, respectively. When the main microphone was covered, the sound leakage for the main microphone was 30.8 dB (=the difference between the sound pressures received by the main microphone and the reference microphone). When the reference microphone was covered, the sound leakage for the reference microphone was 28.7 dB (=the difference between the sound pressures received by the main microphone and the reference microphone).

To meet practical requirements, sound leakage for each microphone exceeding 15 dB was allowed, for consideration of passed data. In table I, failed data (less than 15 dB) are boldfaced. The failed data were obtained when Holder I was mated with jig 2 and jig 4. Note that jig 2 and jig 4 had larger inner diameters than jig 3 (the standard jig). However, Holder II passed the test.

Table II shows another test result, made on Dec. 27, 2007, wherein another main microphone and another reference microphone were used for the test.

TABLE II

| | Main- | | Main- | |
|---|---|---|---|---|
| | MicSens | RefMicSens | Leakage | RefLeakage |
| Jig 1 + Holder I | −16.4 dB | −15.9 dB | 21.6 dB | 24.7 dB |
| Jig1 + Holder I | −16.3 dB | −15.9 dB | 21.1 dB | 24.2 dB |
| Jig 1 + Holder II | −14.8 dB | −14.5 dB | 19 dB | 20 dB |
| Jig 1 + Holder II | −14.7 dB | −14.4 dB | 20.2 dB | 51.5 dB |
| Jig 1 + Holder II | −14.3 dB | −14.1 dB | 20.5 dB | 17.5 dB |
| Jig 2 + Holder I | −16.9 dB | −17.8 dB | 18.3 dB | 6.1 dB |
| Jig 2 + Holder I | −16.6 dB | −17.8 dB | 18.1 dB | 6.2 dB |
| Jig 2 + Holder I | −19.4 dB | −20.3 dB | 18.6 dB | 6.6 dB |
| Jig 2 + Holder II | −16 dB | −15.5 dB | 51.5 dB | 19.3 dB |
| Jig 2 + Holder II | −15.5 dB | −14.8 dB | 50.6 dB | 16.6 dB |
| Jig 2 + Holder II | −16.9 dB | −17 dB | 51.5 dB | 20.5 dB |
| Jig 2 + Holder II | −17 dB | −16.6 dB | 51.2 dB | 52.2 dB |
| Jig 2 + Holder II | −17 dB | −16.7 dB | 51.3 dB | 16.1 dB |
| Jig 3 + Holder I | −19.6 dB | −19.2 dB | 18.1 dB | 16.8 dB |
| Jig 3 + Holder I | −19.5 dB | −19.1 dB | 17.6 dB | 18.3 dB |
| Jig 3 + Holder I | −17.4 dB | −16.6 dB | 51.2 dB | 17.1 dB |
| Jig 3 + Holder I | −17.4 dB | −16.5 dB | 19.2 dB | 18.1 dB |
| Jig 3 + Holder II | −15.7 dB | −13.9 dB | 49.4 dB | 54 dB |
| Jig 3 + Holder II | −15.5 dB | −13.7 dB | 17.6 dB | 18.4 dB |
| Jig 3 + Holder II | −15.6 dB | −13.9 dB | 50 dB | 53.7 dB |
| Jig 3 + Holder II | −17.3 dB | −16.1 dB | 50.1 dB | 52.6 dB |
| Jig 3 + Holder II | −17 dB | −15.9 dB | 50.1 dB | 52.5 dB |
| Jig 4 + Holder I | −19.7 dB | −19.4 dB | 8.5 dB | 13.8 dB |
| Jig 4 + Holder I | −19.7 dB | −19.4 dB | 10.7 dB | 14.8 dB |
| Jig 4 + Holder I | −17.7 dB | −17.1 dB | 13.9 dB | 14.9 dB |
| Jig 4 + Holder I | −17.8 dB | −17.1 dB | 14 dB | 14.9 dB |
| Jig 4 + Holder II | −15.7 dB | −13.7 dB | 49.9 dB | 54.2 dB |
| Jig 4 + Holder II | −15.5 dB | −13.5 dB | 50 dB | 54.2 dB |
| Jig 4 + Holder II | −16.5 dB | −15.5 dB | 50.3 dB | 52.9 dB |
| Jig 4 + Holder II | −16.7 dB | −15.4 dB | 50.4 dB | 52.8 dB |
| Jig 5 + Holder I | −18.6 dB | −17.2 dB | 15.3 dB | 22.3 dB |
| Jig 5 + Holder I | −18.6 dB | −17.1 dB | 16 dB | 22.1 dB |
| Jig 5 + Holder I | −16.7 dB | −15.4 dB | 50.7 dB | 53.5 dB |
| Jig 5 + Holder I | −16.5 dB | −15.3 dB | 50.9 dB | 53.5 dB |
| Jig 5 + Holder II | −15.2 dB | −14.2 dB | 51.1 dB | 52.9 dB |
| Jig 5 + Holder II | −14.8 dB | −14.3 dB | 51.4 dB | 53 dB |
| Jig 5 + Holder II | −16.6 dB | −15.9 dB | 50.8 dB | 52.2 dB |
| Jig 5 + Holder II | −16.3 dB | −15.9 dB | 51 dB | 52.1 dB |

In table II, failed data (less than 15 dB) are boldfaced. Similarly, the failed data were obtained when Holder I was mated with jig 2 and jig 4.

From Table I and Table II, it is shown that Holder II allows a wider tolerance range of the chamber without sound leakage.

Table III shows another test result for plotting the polar pattern for a microphone array. The microphone array containing two omni-directional microphones was disposed in Holder I or Holder II, and then fixed by jig 1. A loudspeaker was disposed in different positions around the microphone array. As shown in Table III, the rms (root mean square) power received by the microphone array was −31.17 dB when the loudspeaker was disposed at 0°. The rms (root mean square) power received by the microphone array was −31.58 dB when the loudspeaker was disposed at 30°. The difference between −31.17 dB and −31.58 dB was −0.41 dB, as shown in the difference column. Data for other loudspeaker degree disposal tests were obtained in a similar manner.

TABLE III

| | Holder I | | Holder II | |
|---|---|---|---|---|
| | Total rms power | | Total rms power | |
| Degree | (dB vrms) | difference | (dB vrms) | difference |
| 0 | −31.17 | 0 | −30.54 | 0 |
| 30 | −31.58 | −0.41 | −31.14 | −0.6 |
| 60 | −46.8 | −15.63 | −46.88 | −16.34 |
| 90 | −49.7 | −18.53 | −48.73 | −18.19 |
| 120 | −48.66 | −17.49 | −49.98 | −19.44 |
| 150 | −42.22 | −11.05 | −41.55 | −11.01 |
| 180 | −35.76 | −4.59 | −34.88 | −4.34 |
| 210 | −51.17 | −20 | −57.05 | −26.51 |
| 240 | −60.04 | −28.87 | −59.37 | −28.83 |
| 270 | −59.71 | −28.54 | −58.95 | −28.41 |
| 300 | −57.03 | −25.86 | −56.62 | −26.08 |
| 330 | −38.27 | −7.1 | −39.14 | −8.6 |

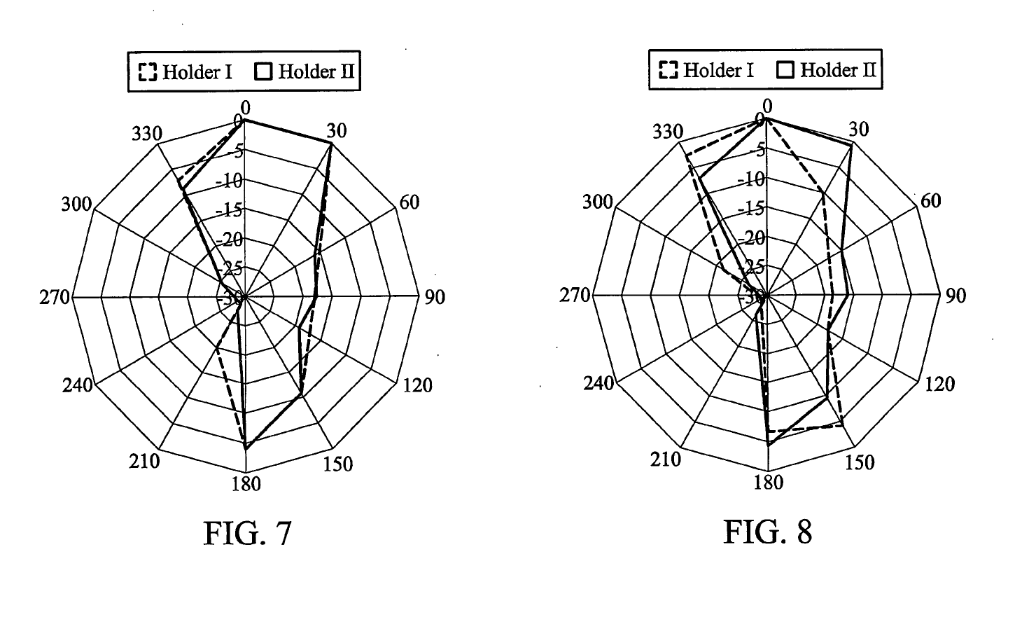

The polar pattern plotted in accordance with Table III is shown in FIG. 7. The pattern for Holder II is narrower than that for Holder I. That is, Holder II provided a narrower beam for picking up sound than Holder I.

Table IV shows another test result for plotting the polar pattern for the same microphone array which was disposed in Holder I or Holder II, and then fixed by jig 2.

TABLE IV

| | Holder I | | Holder II | |
|---|---|---|---|---|
| | Total rms power | | Total rms power | |
| Degree | (dB vrms) | difference | (dB vrms) | difference |
| 0 | −29.77 | 0 | −29.6 | 0 |
| 30 | −40.35 | −10.58 | −30.47 | −0.87 |
| 60 | −47.69 | −17.92 | −44.42 | −14.82 |
| 90 | −48.57 | −18.8 | −45.65 | −16.05 |
| 120 | −47.46 | −17.69 | −47.33 | −17.73 |
| 150 | −33.8 | −4.03 | −39.2 | −9.6 |
| 180 | −36.55 | −6.78 | −33.84 | −4.24 |
| 210 | −57.94 | −28.17 | −56.16 | −26.56 |
| 240 | −59.12 | −29.35 | −58.99 | −29.39 |
| 270 | −58.11 | −28.34 | −58.42 | −28.82 |
| 300 | −51.38 | −21.61 | −56.08 | −26.48 |
| 330 | −32.32 | −2.55 | −36.91 | −7.31 |

The polar pattern plotted in accordance with Table IV is shown in FIG. 8. The pattern for Holder II is narrower than that for Holder I. That is, Holder II provided a narrower beam for picking up sound than Holder I.

Table V shows another test result for plotting the polar pattern for the same microphone array which was disposed in Holder I or Holder II, and then fixed by jig 3.

TABLE V

| | Holder I | | Holder II | |
|---|---|---|---|---|
| | Total rms power | | Total rms power | |
| Degree | (dB vrms) | difference | (dB vrms) | difference |
| 0 | −30.76 | 0 | −29.81 | 0 |
| 30 | −31.69 | −0.93 | −31.35 | −1.54 |
| 60 | −48.7 | −17.94 | −50 | −20.19 |
| 90 | −52.87 | −22.11 | −50.21 | −20.4 |
| 120 | −51.94 | −21.18 | −50.46 | −20.65 |
| 150 | −41.87 | −11.11 | −41.08 | −11.27 |
| 180 | −35.09 | −4.33 | −34.34 | −4.53 |
| 210 | −57.05 | −26.29 | −56.32 | −26.51 |
| 240 | −59.63 | −28.87 | −58.49 | −28.68 |
| 270 | −59.26 | −28.5 | −58.19 | −28.38 |
| 300 | −56.53 | −25.77 | −56 | −26.19 |
| 330 | −37.42 | −6.66 | −37.45 | −7.64 |

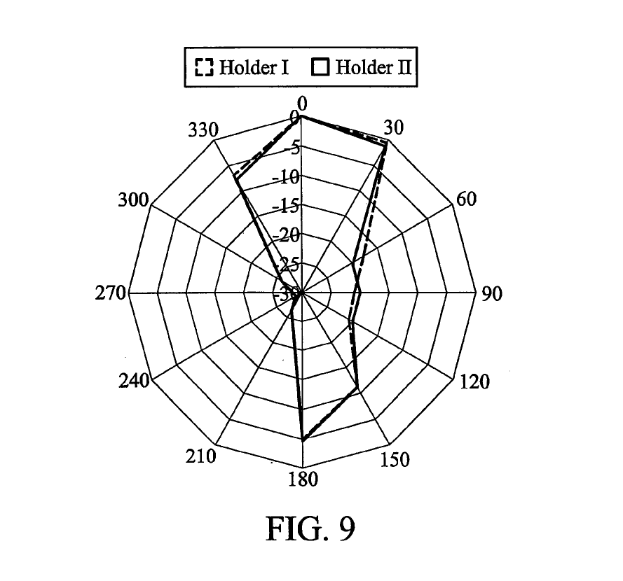

The polar pattern plotted in accordance with Table V is shown in FIG. 9. The pattern for Holder II is narrower than that for Holder I. That is, Holder II provided a narrower beam for picking up sound than Holder I.

Table VI shows another test result for plotting the polar pattern for the same microphone array which was disposed in Holder I or Holder II, and then fixed by jig 4.

TABLE VI

| | Holder I | | Holder II | |
|---|---|---|---|---|
| | Total rms power | | Total rms power | |
| Degree | (dB vrms) | difference | (dB vrms) | difference |
| 0 | −34.12 | 0 | −30.12 | 0 |
| 30 | −31.4 | 2.72 | −31.78 | −1.66 |
| 60 | −49.3 | −15.18 | −51.52 | −21.4 |
| 90 | −53.44 | −19.32 | −52.92 | −22.8 |
| 120 | −54.35 | −20.23 | −52.41 | −22.29 |
| 150 | −52.58 | −18.46 | −42.13 | −12.01 |
| 180 | −38.65 | −4.53 | −34.84 | −4.72 |
| 210 | −46.28 | −12.16 | −55.83 | −25.71 |
| 240 | −60.19 | −26.07 | −58.67 | −28.55 |
| 270 | −60.11 | −25.99 | −58.3 | −28.18 |
| 300 | −58.53 | −24.41 | −56.08 | −25.96 |
| 330 | −55.03 | −20.91 | −38.4 | −8.28 |

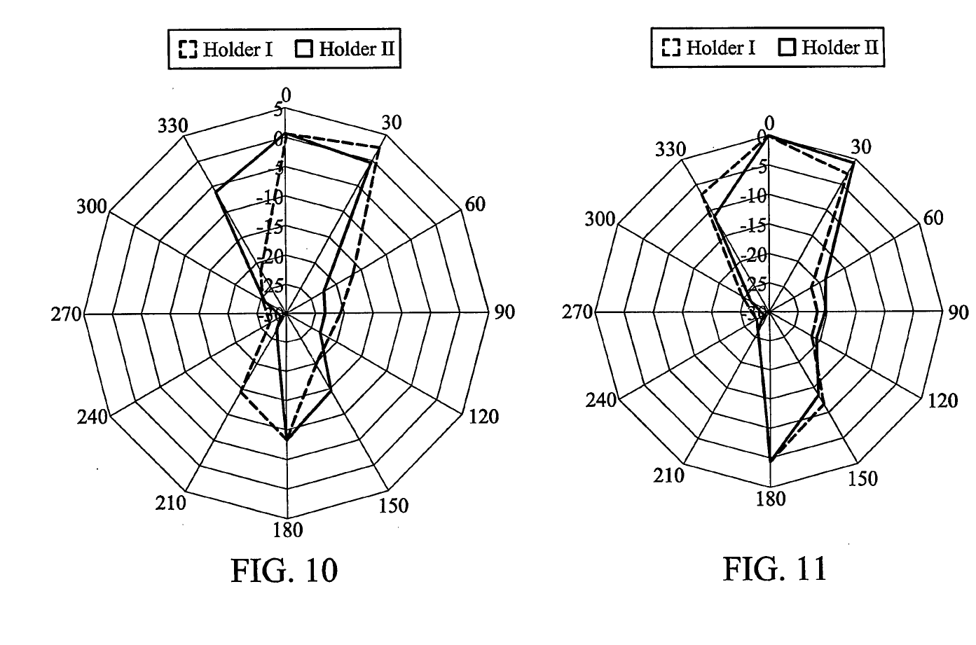

The polar pattern plotted in accordance with Table VI is shown in FIG. 10. The pattern for Holder II is narrower than that for Holder I. That is, Holder II provided a narrower beam for picking up sound than Holder I.

Table VII shows another test result for plotting the polar pattern for the same microphone array which was disposed in Holder I or Holder II, and then fixed by jig 5.

TABLE VII

| | Holder I | | Holder II | |
|---|---|---|---|---|
| | Total rms power | | Total rms power | |
| Degree | (dB vrms) | difference | (dB vrms) | difference |
| 0 | −29.61 | 0 | −31.61 | 0 |
| 30 | −30.38 | −0.77 | −34.72 | −3.11 |
| 60 | −48.13 | −18.52 | −53.48 | −21.87 |
| 90 | −49.95 | −20.34 | −53.57 | −21.96 |
| 120 | −50.57 | −20.96 | −53.53 | −21.92 |
| 150 | −43.54 | −13.93 | −44.05 | −12.44 |
| 180 | −34.11 | −4.5 | −36 | −4.39 |
| 210 | −55.96 | −26.35 | −57.32 | −25.71 |
| 240 | −59 | −29.39 | −58.8 | −27.19 |
| 270 | −58.81 | −29.2 | −58.39 | −26.78 |
| 300 | −56.56 | −26.95 | −56.17 | −24.56 |
| 330 | −40.85 | −11.24 | −38.43 | −6.82 |

The polar pattern plotted in accordance with Table VII is shown in FIG. 11. The pattern for Holder II is narrower than that for Holder I. That is, Holder II provided a narrower beam for picking up sound than Holder I.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electronic device, comprising:
a housing comprising a plurality of wall portions, a plurality of storage spaces encircled by the wall portions, and a plurality of acoustic openings connected to the storage spaces;
a circuit board;
a plurality of flexible holders disposed in the storage spaces, wherein each of the flexible holders comprises a plurality of surfaces and at least one rib provided on the surfaces; and
a plurality of microphones mounted on the circuit board and disposed in the flexible holders.

2. The electronic device as claimed in claim 1, wherein the surfaces of each of the flexible holders include a front surface, a rear surface, and a plurality of side surfaces connected between the front surface and the rear surface, wherein the rib is provided on the front surface.

3. The electronic device as claimed in claim 2, wherein the front surface of each of the flexible holders has a first hole, and the first hole is encircled by the rib and connected to one of the acoustic openings.

4. The electronic device as claimed in claim 3, wherein the rear surface of each of the flexible holders has a second hole, and a diameter of the second hole exceeds that of the first hole.

5. The electronic device as claimed in claim 1, wherein the surfaces of each of the flexible holders include a front surface, a rear surface, and a plurality of side surfaces connected between the front surface and the rear surface, wherein the rib is provided on the side surfaces.

6. The electronic device as claimed in claim 5, wherein the front surface of each of the flexible holders has a first hole, and the first hole is connected to one of the acoustic openings.

7. The electronic device as claimed in claim 6, wherein the rear surface of each of the flexible holders has a second hole, and a diameter of the second hole exceeds that of the first hole.

8. The electronic device as claimed in claim 1, wherein the flexible holders are substantially cylindrical.

9. The electronic device as claimed in claim 1, wherein the flexible holders are made of rubber.

10. The electronic device as claimed in claim 1, wherein the microphones constitute a microphone array.

11. A flexible holder, comprising:
a front surface;
a rear surface;
a plurality of side surfaces connected between the front surface and the rear surface;
a first hole provided on the front surface;
a second hole provided on the rear surface, wherein a diameter of the second hole exceeds that of the first hole; and
a rib provided on the front surface or the side surfaces.

12. The electronic device as claimed in claim 11, wherein the first hole is encircled by the rib when the rib is provided on the front surface.

13. The electronic device as claimed in claim 11, wherein the flexible holder is substantially cylindrical.

14. The electronic device as claimed in claim 11, wherein the flexible holder is made of rubber.
